(19) United States
(12) Patent Application Publication
(10) Pub. No.: US 2010/0159637 A1
(43) Pub. Date: Jun. 24, 2010

(54) Antimony precursor, phase-change memory device using the antimony precursor, and method of manufacturing the phase-change memory device

(75) Inventors: Jung-hyun Lee, Yongin-si (KR); Young-soo Park, Suwon-si (KR); Sung-ho Park, Seongnam-si (KR)

Correspondence Address: LEE & MORSE, P.C., 3141 FAIRVIEW PARK DRIVE, SUITE 500, FALLS CHURCH, VA, 22042, US

(73) Assignee: SAMSUNG ELECTRONICS CO., LTD., Suwon-si (KR)

(21) Appl. No.: 12/654,839

(22) Filed: Jan. 6, 2010

Related U.S. Application Data
(62) Division of application No. 11/219,805, filed on Sep. 7, 2005, now abandoned.

(30) Foreign Application Priority Data
Sep. 8, 2004 (KR) 10-2004-0071868

(51) Int. Cl. H01L 21/06; C07F 7/10

(52) U.S. Cl. 438/102; 556/12; 257/E21.068

(57) ABSTRACT

An antimony precursor including antimony, nitrogen and silicon, a phase-change memory device using the same, and a method of making the phase-change memory device. The phase-change memory device may have a phase-change film of a Ge₂—Sb₂—Te₅ material including nitrogen and silicon.

### CROSS REFERENCE TO RELATED APPLICATION

This is a divisional application based on pending application Ser. No. 11/219,805, filed Sep. 7, 2005, the entire contents of which is hereby incorporated by reference.

### BACKGROUND OF THE INVENTION

1. Field of the Invention

The present invention relates to a precursor for forming a phase-change film and a memory device using the same. More particularly, the present invention relates to a precursor for forming a phase-change film for a Phase-change Random Access Memory (PRAM) that can reduce a reset current and a memory device using the precursor.

2. Description of the Related Art

Phase-change materials may undergo a structural transformation between crystalline and amorphous phases. The crystalline phase may exhibit a lower resistance relative to the amorphous phase and have a more orderly atomic arrangement. The crystalline phase and the amorphous phase may be reversibly changed. That is, the conversion of the crystalline phase to the amorphous phase, and vice versa, is possible. Phase-change Random Access Memories (PRAMs) are devices based on a reversible phase change between crystalline and amorphous phases that have distinctly different resistances. Various types of phase-change materials that can be applied to memory devices are known. A GST (GeSbTe, germanium-antimony-tellurium)-based alloy is a typical phase-change material.

PRAMs may have a general structure where a phase-change film is electrically connected to a source region or a drain region of a transistor via a contact plug. PRAMs typically operate on a resistance difference due to a change in the crystal structure of a phase-change film.

FIG. 1 illustrates a conventional PRAM, the general structure of which will now be described. Referring to FIG. 1, a semiconductor substrate 10 may be formed with a first impurity region 11a and a second impurity region 11b. A gate insulating layer 12 may be formed on the semiconductor substrate 10 to contact the first impurity region 11a and the second impurity region 11b, and a gate electrode layer 13 may be formed on the gate insulating layer 12. The first impurity region 11a may be designated the “source” and the second impurity region 11b may be designated the “drain.”

The first impurity region 11a, the gate electrode layer 13 and the second impurity region 11b may be covered with an insulating layer 15. A contact plug 14 may be formed through the insulating layer 15 to contact the second impurity region 11b. A lower electrode 16 may be formed on the contact plug 14. A phase-change film 17 and an upper electrode 18 may be formed on the lower electrode 16.

Data storage in the above-described PRAM may be accomplished as follows. When a current is applied to the second impurity region 11b and the lower electrode 16, Joule heat is generated at a contact area of the lower electrode 16 and the phase-change film 17. Therefore, the crystal structure of the phase-change film 17 may be changed, resulting in data storage. That is, the crystal structure of the phase-change film 17 may be changed into a crystalline phase or an amorphous phase by appropriately adjusting an applied current. Such a phase change between a crystalline phase and an amorphous phase leads to a change in resistance, which enables identification of stored binary data values.

To enhance the performance of memory devices, a power consumption (current) should be reduced. In particular, a PRAM using GST typically requires a high reset current, i.e., a high current to induce the transition from a crystalline phase to an amorphous phase.

FIG. 2 illustrates a graph of a heating temperature for reset/set programming of a memory device including a GST (Ge₂Sb₂Te₅) phase-change film. Referring to FIG. 2, set programming, i.e., the transition from an amorphous phase to a crystalline phase, may be accomplished at a temperature below the melting temperature (Tₘ) of GST during a predetermined time. On the other hand, reset programming, i.e., the transition from a crystalline phase to an amorphous phase, may be accomplished by heating the GST to its melting temperature (Tₘ) and then quenching. A relatively high current is required to reach the melting point of GST. This high current may be problematic in constructing highly integrated memory devices.

A phase-change film may be formed by sputtering using targets of a Ge—Sb—Te material and may then be doped with nitrogen or silicon by a separate doping process, i.e., by separately performing a GST phase-change film formation process and a nitrogen or silicon doping process.

### SUMMARY OF THE INVENTION

The present invention is therefore directed to a precursor used for forming a phase-change film and a memory device using the same, which substantially overcome one or more of the problems due to the limitations and disadvantages of the related art.

It is therefore a feature of an embodiment of the present invention to provide a precursor for forming a phase-change film that can reduce the intensity of an applied current necessary for change in crystal structure of a phase-change film, e.g., a reset/set programming current in a PRAM, to enable highly integrated, high capacity and high speed semiconductor memory devices.

It is therefore another feature of an embodiment of the present invention to provide a precursor for forming a phase-change including a nitrogen- and silicon-doped GST film.

At least one of the above and other features and advantages of the present invention may be realized by providing an antimony-containing compound including antimony, nitrogen and silicon.

The compound may include three nitrogen atoms covalently bound to an antimony atom. Each of the three nitrogen atoms may be covalently bound to two silicon atoms. Each silicon atom may be bound to three methyl groups. The compound may be a compound represented by the formula SbN₃Si₆(CH₃)₁₈. The compound may be a compound represented by structure 1:

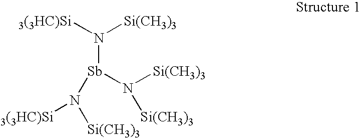

At least one of the above and other features and advantages of the present invention may also be realized by providing a phase-change memory device including a semiconductor substrate including a transistor structure and a storage element electrically connected to the transistor structure, wherein the storage element may include a nitrogen- and silicon-containing GST phase-change film interposed between two conductive elements.

The phase-change memory device may include a nitrogen- and silicon-containing GST phase-change film of a Ge₂—Sb₂—Te₅ material including nitrogen and silicon. The nitrogen- and silicon-containing GST phase-change film may reversibly change between a crystalline phase and an amorphous phase when heated by an electric current passed between the two conductive elements.

At least one of the above and other features and advantages of the present invention may further be realized by providing a method of manufacturing a memory device including a phase-change film, the method including forming the phase-change film using an antimony precursor including antimony, nitrogen and silicon.

The antimony precursor may be a material represented by the formula SbN₃Si₆(CH₃)₁₈. The antimony precursor may be a material represented by structure 1:

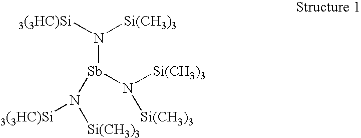

The phase-change film may be formed by chemical vapor deposition or atomic layer deposition. The method may also include forming a phase-change storage element on the substrate, the phase-change storage element including the phase-change film interposed between two electrically conductive elements, wherein forming the phase-change film includes providing the antimony precursor, a germanium precursor, and a tellurium precursor. The antimony precursor, the germanium precursor, and the tellurium precursor may be provided concurrently, or may be provided sequentially. The method may also include causing the antimony precursor, the germanium precursor and the tellurium precursor to react to form the phase-change film, wherein the phase-change film is a GST film that includes nitrogen and silicon.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a schematic sectional view of a conventional Phase-change Random Access Memory (PRAM);

FIG. 2 illustrates a graph of a heating temperature for reset/set programming of a memory device including a GST (Ge₂Sb₂Te₅) phase-change film;

FIG. 3 illustrates a view of a reset current (mA) with respect to the type of a phase-change film;

FIGS. 4A and 4B illustrate views of the synthesis of a precursor of a phase-change material according to an embodiment of the present invention;

FIG. 5 illustrates a Thermal Gravimetric Analysis (TGA) graph of a solution containing a solvent and an antimony precursor; and

FIG. 6 illustrates a schematic sectional view of a phase-change memory device according to the present invention.

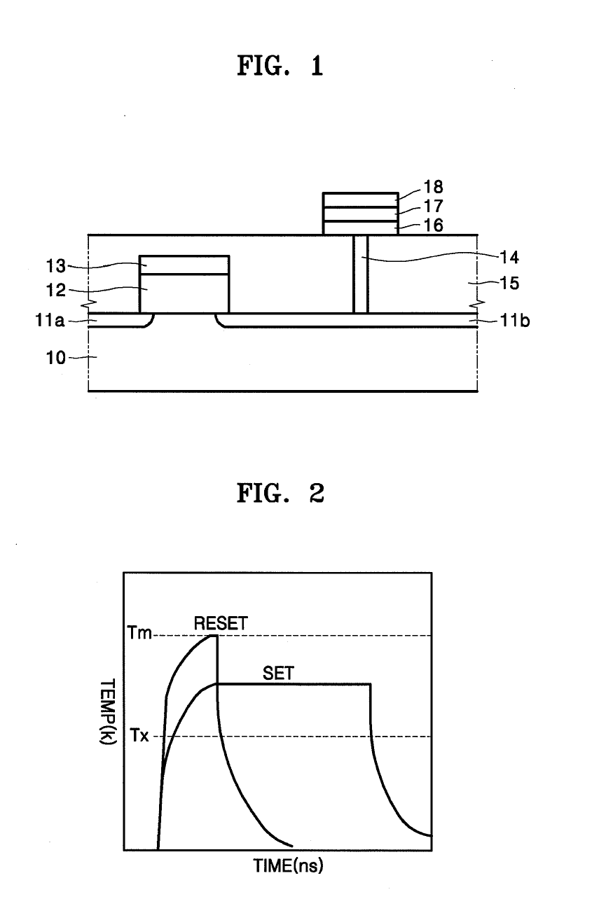

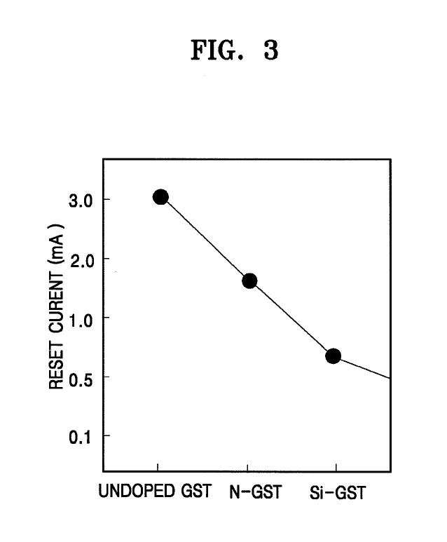

### DETAILED DESCRIPTION OF THE INVENTION

Korean Patent Application No. 10-2004-0071868, filed on Sep. 8, 2004, in the Korean Intellectual Property Office, and entitled: “Antimony Precursor, Phase-change Memory Device Using the Antimony Precursor, and Method of Manufacturing the Phase-change Memory Device,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A precursor of a phase-change material according to the present invention, and a phase-change memory device using the same, will now be described more fully with reference to the accompanying drawings, in which exemplary embodiments of the invention are illustrated.

FIG. 3 illustrates a view of a reset current (mA) with respect to the type of a phase-change film. This particular example includes three Phase-change Random Access Memories (PRAMs), including upper and lower electrodes made of TiN and phase-change films, interposed between the upper and lower electrodes, made of undoped GST (Ge₂Sb₂Te₅), nitrogen (N)-doped GST, and silicon (Si)-doped GST, respectively. An amount of current required for inducing a transition from a crystalline phase to an amorphous phase of the phase-change films, i.e., the reset current, was measured.

Referring to FIG. 3, the undoped GST-based PRAM operated with the highest reset current, 3 mA, the N-doped GST-based PRAM operated with a reset current of about 1.5 mA and the Si-doped GST-based PRAM operated with the lowest reset current, about 0.7 mA. Thus, a N- or Si-doped GST phase-change film may remarkably reduce the reset current while maintaining phase-change characteristics. This might be because silicon or nitrogen contained as an impurity in a GST phase-change film facilitates crystalline to amorphous phase transition at a relatively low temperature, although it is noted that the present invention is not limited to this theory of operation.

Typically, the formation of a phase-change film on a lower electrode of a memory device is performed by Chemical Vapor Deposition (CVD) or Atomic Layer Deposition (ALD). To perform CVD or ALD, the use of a suitable precursor for CVD or ALD is essential. The present invention provides a precursor for CVD or ALD that may be used for forming a N- or Si-doped GST phase-change film.

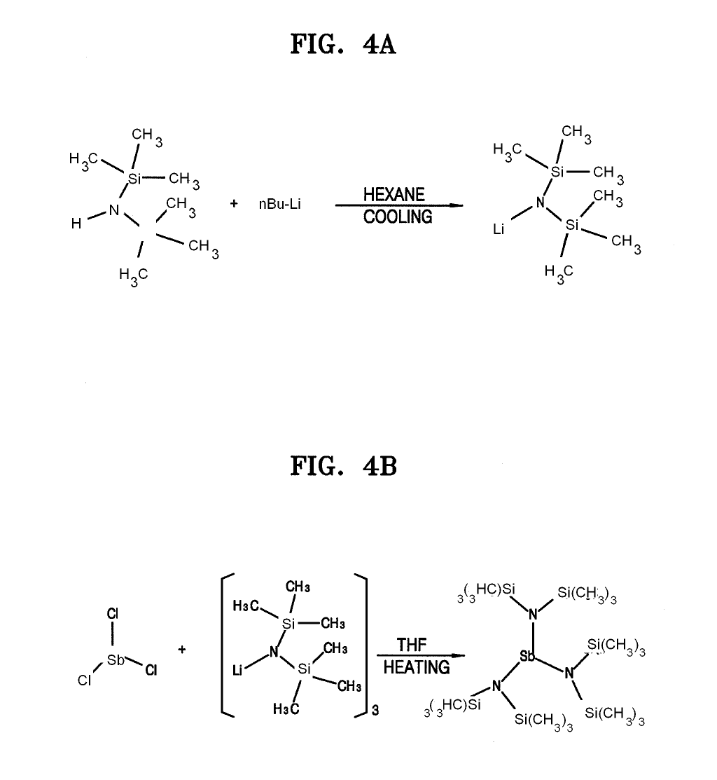

FIGS. 4A and 4B illustrate views of the synthesis of a precursor of a phase-change material according to an embodiment of the present invention. The present invention provides a N- and Si-containing antimony precursor, resulting in inclusion of nitrogen and silicon in a GST phase-change film, thereby reducing the reset current of the GST phase-change film.

Referring to FIG. 4A, Li—N-2(Si-3R) may be formed by a substitution reaction, wherein hydrogen (H) of the compound H—N—2(Si-3R) (R: methyl group, CH₃) is substituted with lithium of n-butyl lithium (nBu—Li) in an inert atmosphere at atmospheric pressure.

Referring to FIG. 4B, an antimony precursor, represented by the formula Sb-3(N-2(Si-3R)) or SbN₃Si₆(CH₃)₁₈, may be synthesized by reacting 3(Li—N-2(Si-3R)) with an antimony compound, e.g., SbCl₃, in a solvent, e.g., tetrahydrofuran (THF), at a temperature in the range of room temperature to about 150° C. in an inert atmosphere at atmospheric pressure. In the antimony precursor thus synthesized, three nitrogen atoms are bound to an antimony atom and each nitrogen atom is bound to two silicon atoms. The antimony precursor may be a material represented by structure 1:

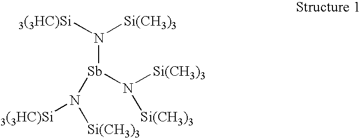

A N- and Si-containing antimony precursor synthesized as described above should exist in a gas phase at high temperature to be used as a precursor for CVD or ALD. However, the binding of nitrogen and silicon with antimony must not be cracked. That is, the precursor should be thermally stable. In this regard, a Thermal Gravimetric Analysis (TGA) for an antimony precursor solution was performed. The TGA was carried out with heating from room temperature to a predetermined temperature to analyze a residual component content.

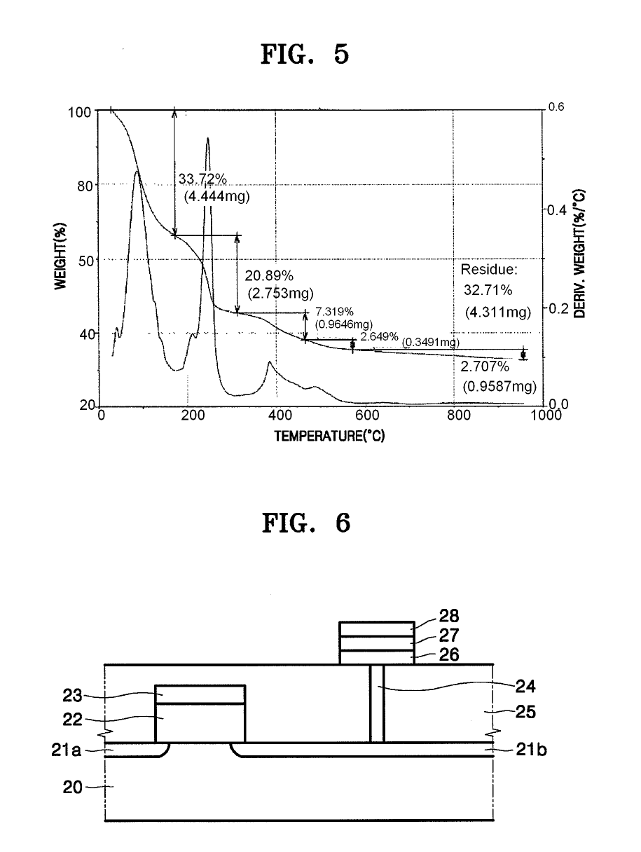

FIG. 5 illustrates a Thermal Gravimetric Analysis (TGA) graph of a solution containing a solvent and an antimony precursor. Referring to FIG. 5, 13.1790 mg of a solution containing a THF solvent and the antimony precursor synthesized as shown in FIG. 4B was heated, increasing from room temperature to 1,000° C. Referring to FIG. 5, about 4.444 mg (33.73 wt %) of the THF solvent was first evaporated at about 170° C. Then, 2.753 mg (20.89 wt %) of CH₃ was evaporated at about 310° C. At about 1,000° C., most of the THF solvent was evaporated and a residual component content was about 4.311 mg (32.71 wt %). The inspection of residual components revealed that significant nitrogen and silicon bound to antimony remained. Thus, the N- and Si-containing antimony precursor synthesized according to the present invention may be used as a precursor for CVD or ALD.

Hereinafter, a phase-change memory device including a phase-change film formed using a N- and Si-containing precursor and a method of manufacturing the same according to the present invention will be described in detail.

FIG. 6 illustrates a schematic sectional view of a phase-change memory device according to the present invention. Referring to FIG. 6, an n- or p-type semiconductor substrate 20 may be formed with a first impurity region 21a and a second impurity region 21b with opposite polarity to the semiconductor substrate 20. A semiconductor substrate region between the first impurity region 21a and the second impurity region 21b may be designated the “channel region.” A gate insulating layer 22 and a gate electrode layer 23 may be formed on the channel region.

The first impurity region 21a, the gate electrode layer 23 and the second impurity region 21b may be covered with an insulating layer 25. A contact hole may be formed in the insulating layer 25 to expose the second impurity region 21b and a conductive plug 24 may be formed in the contact hole. A lower electrode 26, a phase-change film 27 and an upper electrode 28 may be sequentially formed on the conductive plug 24. The phase-change film 27 may be a Si- and N-containing GST phase-change film according to the present invention. Generally, the transistor structure below the phase-change film 27 may be manufactured by typical semiconductor fabrication process.

In the structure illustrated in FIG. 6, the lower electrode 26 and the conductive plug 24 may be integrally formed. That is, the phase-change film 27 may be directly formed on the conductive plug 24 so that the conductive plug 24 serves as the lower electrode 26. Direct current applied to the conductive plug 24 may generate Joule heat such that the conductive plug 24 may be used as a heating plug.

A method of manufacturing a phase-change memory device according to the present invention will now be described with reference to FIG. 6. First, a gate insulating layer material and a gate electrode layer material may be sequentially coated on the semiconductor substrate 20. Then, the gate insulating layer material and the gate electrode layer material, except those portions intended for the gate insulating layer 22 and the gate electrode layer 23, may be removed to form the gate insulating layer 22 and the gate electrode layer 23. Exposed surface regions of the semiconductor substrate 20 may be doped with an impurity to form the first impurity region 21a and the second impurity region 21b. Then, the insulating layer 25 may be formed on the first impurity region 21a, the gate electrode layer 23 and the second impurity region 21b. A contact hole may be formed in the insulating layer 25 to expose the second impurity region 21b. The contact hole may be filled with a conductive material to form the conductive plug 24.

A conductive material, e.g., a noble metal material, a metal nitride such as TiN, etc., may be selectively formed on the conductive plug 24 to form the lower electrode 26. The phase-change film 27 may be formed on the lower electrode 26, although, as noted above, the lower electrode 26 may be eliminated and the phase-change film 27 may be formed on the conductive plug 24.

The phase-change film 27 of the present invention may be formed by reacting a N- and Si-containing antimony precursor, a Ge-containing precursor and a Te-containing precursor on the substrate 20 in a reaction chamber. Finally, a conductive material, e.g., the same conductive material as the lower electrode 26, may be coated on the phase-change film 27 to form the upper electrode 28 to complete a phase-change memory device according to the present invention.

A precursor of a phase-change material according to the present invention may reduce the intensity of an applied current necessary for inducing a change in the crystal structure of a phase-change film, thereby enabling highly integrated, high capacity and high speed semiconductor memory devices.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. An antimony-containing compound comprising antimony, nitrogen and silicon.

2. The antimony-containing compound as claimed in claim 1, wherein three nitrogen atoms are covalently bound to an antimony atom and each of the three nitrogen atoms is covalently bound to two silicon atoms.

3. The antimony-containing compound as claimed in claim 2, wherein each silicon atom is bound to three methyl groups.

4. The antimony-containing compound as claimed in claim 1, wherein the compound is represented by the formula SbN₃Si₆(CH₃)₁₈.

5. The antimony-containing compound as claimed in claim 1, wherein the compound is represented by structure 1:

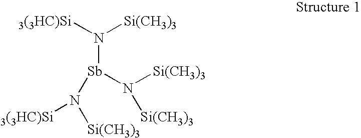

6. (canceled)

7. (canceled)

8. (canceled)

9. A method of manufacturing a memory device having a phase-change film, the method comprising forming the phase-change film using an antimony precursor including antimony, nitrogen and silicon.

10. The method as claimed in claim 9, wherein the antimony precursor is a material represented by the formula SbN₃Si₆(CH₃)₁₈.

11. The method as claimed in claim 9, wherein the antimony precursor is represented by structure 1:

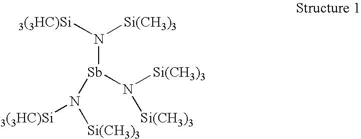

12. The method as claimed in claim 9, wherein the phase-change film is formed by chemical vapor deposition or atomic layer deposition.

13. The method as claimed in claim 9, further comprising:
forming a phase-change storage element on the substrate, the phase-change storage element including the phase-change film interposed between two electrically conductive elements, wherein forming the phase-change film includes providing the antimony precursor, a germanium precursor, and a tellurium precursor.

14. The method as claimed in claim 13, wherein the antimony precursor, the germanium precursor, and the tellurium precursor are provided concurrently.

15. The method as claimed in claim 13, wherein the antimony precursor, the germanium precursor, and the tellurium precursor are provided sequentially.

16. The method as claimed in claim 13, further comprising causing the antimony precursor, the germanium precursor and the tellurium precursor to react to form the phase-change film, wherein the phase-change film is a GST film that includes nitrogen and silicon.
